(19) United States
(12) Patent Application Publication
(10) Pub. No.: US 2008/0023070 A1
(43) Pub. Date: Jan. 31, 2008

(54) Methods and systems for manufacturing polycrystalline silicon and silicon-germanium solar cells

(76) Inventor: Sanjai Sinha, Pleasanton, CA (US)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 11/881,501

(22) Filed: Jul. 26, 2007

Related U.S. Application Data
(60) Provisional application No. 60/833,630, filed on Jul. 28, 2006.

(51) Int. Cl. H01L 31/18; H01L 31/00

(52) U.S. Cl. 136/261; 118/724; 427/452; 427/74

(57) ABSTRACT

The present invention relates to a novel, unconventional methods and systems for the fabrication of silicon or silicon-germanium photovoltaic cell applications. In some embodiments high purity gaseous and/or liquid intermediate compounds of silicon (or silicon germanium) are converted directly to polycrystalline films by a thermal plasma chemical vapor deposition process or by a thermal plasma spraying technique. The intermediate compounds of silicon (or silicon germanium) are injected into the thermal plasma source where temperatures range from 2000 K to about 20,000 K. The compounds dissociate and silicon (or silicon germanium) is deposited onto substrates. Polycrystalline films having densities approaching the bulk value are obtained on cooling. PN junction photovoltaic cells can be directly prepared by spraying, or doped films after heat treatment are subsequently transformed to viable photovoltaic cells having high efficiency, low cost at a high throughput. In some embodiments a roll-to-roll or a cluster-tool type automated, continuous system is provided.

### RELATED APPLICATIONS

This application claims the benefit of, and priority to, U.S. provisional patent application Ser. No. 60/833,630 filed on Jul. 28, 2006, the disclosure of which is incorporated by reference herein in its entirety.

### FIELD OF THE INVENTION

In general, the present invention is directed to methods and systems for producing photovoltaic devices or solar cells. More specifically, the present invention is directed to methods and systems for producing polycrystalline silicon and silicon-germanium solar cells at reduced cost and with high efficiency.

### BACKGROUND OF THE INVENTION

Electric power generation from silicon photovoltaic devices has gone through significant cost reductions over the years. Widespread adoption, however, will require further breakthroughs in these costs to lower than $1.00/watt levels. There is a growing belief that these further step function decreases are not likely to come from silicon based cells, as evidenced by a trend towards development of alternative materials such as CIGS, CdTe and amorphous silicon. Most prevailing processes are based upon working with silicon in wafer form. Breakthrough cost reductions will require, among other things, a drastic reduction in both the cost of producing wafers and the thickness of wafers. To a great extent, the potential of both of these options has already been exhausted.

The current preferred method in the production of high purity silicon is the Siemens process, and the overall silicon process consists of seven or more steps as shown in simplified schematic drawings in FIGS. 1A and 1B. In general, the conventional process includes reduction of quartz with carbon to produce metallurgical grade silicon in step 101, conversion of metallurgical grade silicon to intermediate compounds such as silane, disilane, mono-chlorosilane, di-chlorosilane, tri-chlorosilane and tetra-chlorosilicon by reaction with hydrogen chloride in step 102, purification to parts per billion or better of the intermediate compounds in step 103, hydrogen reduction and pyrolysis of the intermediate compounds to high purity bulk polycrystalline silicon in step 104, the bulk silicon is then re-melted and growth of single crystal, doped boules of silicon from the polycrystalline silicon is carried out in step 105, sawing of the boules to wafers in step 106, and chemical-mechanical polishing of the wafer to produce polished wafers in step 107. FIG. 1B shows an example of the per kilogram cost at each stage of the process. As illustrated the cost increases significantly in the final three steps of the process where the single crystal boules are grown, wafers are sawed and then polished. Moreover, after decades of effort, the reduction in cost per watt of silicon based solar cells is showing signs of having plateaued.

Silicon solar cell device processing is divided into single crystal and polycrystalline solar cell technology and involves a myriad of steps. In single crystal solar cell technology the same general process is employed, however, the conventional silicon wafer production process is intercepted at the end of step 107 (FIGS. 1A and 2), and commercial devices 111 (FIG. 2) with efficiencies ranging between 12 to 24% are produced. In polycrystalline solar cell technology, the conventional silicon wafer production process is intercepted at the end of step 104 as illustrated in FIGS. 2 and 3. Specifically, the bulk silicon is re-melted, and large grain size polycrystalline ingots are cast and morphed to wafers, or ribbons are pulled, or films on substrates are grown. Commercial devices with efficiencies ranging from 10 to 20% are produced from these wafers, ribbons and films. Whether ingots 108 or boules 105 are used, it is still necessary to re-melt the bulk silicon, saw the ingot into wafers at step 109 and polish the wafers at step 110 to produce the polycrystalline device 111. Some modifications have been made as shown in FIG. 3, where films 112 or ribbons 113 are used to form a device 111, but again it is still necessary to re-melt the bulk silicon.

Moreover, the two processes in tandem lead to inherently expensive solar cells and exceeds the key industry metric of “Cost per Watt” thus limiting widespread acceptance and deployment of conventional photovoltaics, as evidenced by an overall movement in the industry towards exploration of materials other than crystalline silicon, such as CIGS, CdTe and amorphous silicon, for achieving cost targets of below $1.00/watt. However, these alternative materials do not have the demonstrated field reliability of silicon and the production processes will potentially create a new set of environmental issues. Thus, new developments and further improvements are greatly needed, in the silicon process.

### SUMMARY OF THE INVENTION

Of particular advantage, the inventor has discovered a novel method and system for manufacturing polycrystalline silicon and silicon-germanium solar cells or photovoltaic devices that overcomes many of the limitations of the conventional process, and enables production of such devices at significantly reduced cost thereby promoting widespread acceptance and adoption of solar cell technology by the public.

In one aspect, embodiments of the present invention provide for preparation of polycrystalline silicon or silicon-germanium films and solar cells from high purity gaseous, liquid precursors, or a mixture of liquid and gaseous precursors, or a mixture of liquid and solid precursors, representing a radical change in the initial form of the silicon precursors used.

In one aspect, embodiments of the present invention provide methods of forming a solar cell or photovoltaic device, characterized in that: one or more silicon intermediates in liquid or gases form are thermally processed with hydrogen to form a polycrystalline silicon film directly on a substrate, wherein said thermal processing is configured to promote enhanced grain quality of the polycrystalline silicon film as formed.

In another aspect, embodiments of the present invention provide methods of forming a solar cell or photovoltaic device, comprising the steps of: generating a plasma stream in a thermal plasma source, injecting one or more silicon intermediate compounds into thermal plasma source wherein the silicon intermediate compounds dissociate, injecting hydrogen into the thermal plasma source, and depositing a polycrystalline silicon film on the surface of one or more substrates located proximate said thermal plasma source, wherein hydrogen is incorporated into the polycrystalline silicon film to promote passivation of silicon grains formed in the polycrystalline silicon film.

Some embodiments of the present invention further provide methods of forming a solar cell or photovoltaic device, comprising the steps of: converting metallurgical grade silicon to one or more silicon intermediate compounds by reaction with hydrogen halides; purifying said silicon intermediate compounds to form silicon intermediate compounds of approximately 99.5% purity and greater; generating a plasma stream in a thermal plasma source; injecting said purified silicon intermediate compounds into the thermal plasma source wherein the silicon intermediate compounds dissociate, injecting hydrogen into the thermal plasma source, and depositing a polycrystalline silicon film on the surface of one or more substrates located proximate said thermal plasma source, said polycrystalline silicon film exhibiting enhanced grain quality and growth rate. Additionally, a solar cell or photovoltaic device comprising a polycrystalline silicon film, or silicon-germanium film, formed according to the recited methods is provided.

In another aspect, a system for manufacturing a solar cell or photovoltaic device is provided, comprising: a handling mechanism configured to support and transport one or more substrates; a plasma chamber comprising a thermal plasma spray gun configured to generate a thermal plasma spray to deposit a polycrystalline silicon or silicon-germanium film on the surface of the one or more substrates as the substrates are conveyed through the plasma chamber; and a post deposition chamber comprising at least one heating mechanism configured to generate a focused linear beam of light that melts the polycrystalline silicon or silicon-germanium film in linear zones as the one or more substrates are conveyed through the post deposition chamber. The molten region recrystallizes as the beam scans away.

In another aspect, a system for manufacturing a solar cell or photovoltaic device is provided, comprising: a handling mechanism configured to support and transport one or more substrates; a plasma chamber comprising a thermal plasma spray gun configured to generate a thermal plasma spray to deposit a polycrystalline silicon or silicon-germanium film on the surface of the one or more substrates as the substrates are conveyed through the plasma chamber; and a post deposition chamber comprising at least one heating mechanism configured to generate a pulsed large area beam of light that melts the polycrystalline silicon or silicon-germanium film as the one or more substrates are conveyed through the post deposition chamber. The molten film recrystallizes after the pulse.

### BRIEF DESCRIPTION OF THE FIGURES

Other aspects, embodiments and advantages of the invention will become apparent upon reading of the detailed description of the invention and the appended claims provided below, and upon reference to the drawings in which:

FIGS. 1A and 1B show simplified schematic process diagrams generally illustrating the conventional Siemens process and the overall silicon process;

FIG. 2 is a simplified schematic process diagram showing a conventional production process to manufacture single crystal silicon and polycrystalline silicon solar cells based on the conventional Siemens process;

FIG. 3 depicts a simplified schematic process diagram of a convention production process to manufacture ribbon and film on substrate silicon solar cells;

FIGS. 4A and 4B illustrate simplified schematic process diagrams showing a system and method for producing silicon solar cells according to some embodiments of the present invention;

FIG. 5 is a simplified cross sectional view showing a system according to some embodiments of the present invention; and

FIG. 6 is a prospective view of one embodiment of a thermal plasma spray gun that may be used in embodiments of the present invention; and

FIG. 7 is a schematic process diagram showing a plasma spray system and method with post treatment steps according to some embodiments of the present invention.

### DETAILED DESCRIPTION OF THE INVENTION

Embodiments of the present invention are now described in detail. In one embodiment, methods of forming a solar cell or photovoltaic device are provided generally comprising the steps of: generating a plasma stream in a thermal plasma source; injecting one or more silicon intermediate compounds in liquid and/or gaseous form into thermal plasma source wherein the silicon intermediate compounds dissociate; injecting hydrogen into the thermal plasma source; and depositing a polycrystalline silicon film on the surface of one or more substrates located proximate said thermal plasma source, wherein hydrogen is incorporated into the polycrystalline silicon film to promote passivation of silicon grains formed in the polycrystalline silicon film.

Of particular advantage, liquid and/or gaseous silicon intermediate compounds are employed. In one preferred embodiment, liquid silicon intermediate compounds having a purity of about 99.5% and greater are used. Examples of suitable silicon intermediates include, without limitation, any one or more of SiH₄, Si₂H₆, SiH₂Cl₂, SiHCl₃, SiCl₄, SiBr₄, SiHBr₃, SiH₂Br₂, SiI₄, SiH₁₃, SiI₂, or combinations thereof. In some embodiments the silicon intermediate compounds are comprised of a mixture of liquid and/or gaseous compounds with solid silicon compounds, or silicon powder. Silicon intermediate compounds may be injected into the thermal plasma source at any suitable flowrate. In one example, the silicon intermediates are injected at a flowrate in the range of approximately 0.1 to 1000 ml/s. Additionally, in some embodiments a layer of silicon particles may first be injected onto said substrates to form a silicon seed layer thereon, prior to injecting the one or more silicon intermediate compounds.

In further embodiments of the present invention, a silicon-germanium film is formed by employing one or more germanium intermediate compounds concurrently or subsequently with the silicon intermediates to form a polycrystalline silicon-germanium film. Examples of suitable germanium intermediate compounds include, without limitation, any one of more of: GeCl₄, GeH₄, or combinations thereof. Of significant advantage, embodiments of the present invention enable the addition of the germanium intermediate compounds to the silicon intermediates to deposit pure or doped polycrystalline silicon-germanium films having tunable Si/Ge ratios.

Of further advantage, doping of the polycrystalline silicon or silicon-germanium film may be accomplished easily during formation of the film. In some embodiments, one or more dopant compounds are mixed concurrently with said silicon intermediates, or subsequently, to form a doped polycrystalline silicon film. Examples of suitable dopant compounds include without limitation any one or more of: BCl₃, AlCl₃ for p-type dopants and POCl₃ for n-type dopants, or combinations thereof.

In general, the polycrystalline silicon or silicon-germanium film is formed by thermal processing. In one preferred embodiment thermal processing is carried out by means of thermal plasma spray techniques as described in detail below. It should be understood by those of skill in the art that other thermal processing techniques may be used given the teaching of the present invention. For example, thermal processing may also be carried out using plasma enhanced chemical vapor deposition techniques and the like.

More specifically, embodiments of the present invention include forming a high temperature gas or plasma comprised of any one or more of helium, hydrogen, argon, or mixtures thereof, which may be used in a thermal plasma spray source. Thermal plasma sources are electrical devices used for generating a high temperature gas, which is partially or completely ionized, also referred to as a “plasma”. In some embodiments argon with hydrogen or helium with hydrogen is used as a high temperature gas for reducing and decomposing the injected intermediate precursors and subsequently depositing the silicon or silicon-germanium film onto one or more substrates to form polycrystalline films. Films can be deposited onto metallic substrates, metalized insulating substrates, among others, and if deposited on removable substrates, freestanding films can be produced.

Methods and systems of the invention may utilize a variety of plasma sources. For example, a DC, RF, or a hybrid DC-RF thermal plasma source may be used for deposition. Typically, the thermal plasma source is operated at a temperature in the range of approximately 2000 K to 20,000 K, and at a power in the range of approximately 1 to 300 KWatt.

In some embodiments the thermal plasma source includes a linearly elongated, shaped nozzle. The plasma source and substrate are typically housed in a chamber, such as a vacuum chamber having suitable effluent gas extraction. One or more substrates may be processed at one time. Alternatively the plasma source and substrate may be housed in an atmospheric pressure chamber or an environmental chamber having suitable effluent gas extraction. In general, deposition is carried out at a pressure in the range of approximately 1 to 760 Torr, or at positive pressure.

Preferably the substrate is located proximate the outlet of the plasma spray source and is positioned perpendicular or at an angle to the plasma plume exiting the plasma source. Generally, the one or more substrates are located proximate the thermal plasma source. The thermal plasma source emits a plasma spray or plume, a portion of which emits lights and is visible. In some embodiments, the one or more substrates are immersed in the visible portion of the plasma plume. Alternatively, the one or more substrates may be located below or downstream of the visual plasma plume. In one embodiment the substrates may be located below or downstream of the plasma plume up to about 10 cm. In another embodiment, the substrates may be located below or downstream of the plasma plume up to about 4 cm. In some embodiments the substrate(s) may be carried on a substrate heater during the deposition process.

Of particular advantage, methods of the present invention allow for deposition on all varieties of substrates. Examples of substrate materials that may be processed to form films thereon according to embodiments of the present invention include, without limitation: metal, semiconductor, insulator, ceramic, metalized non-conductors, glass, any dielectric material, or combinations thereof. Further, the plasma spray deposition technique of the present invention enables deposition of films directly on a variety of substrate shapes, and the invention is not limited to planar substrates. Curved, complex geometry, and other non-planar substrates may be employed. Metallized non-conducting substrates may be formed using elemental metals, conducting metal borides (such as for example: AlB₂, TiB₂ and the like), conducting metal nitrides, and conducting metal silicides.

As described above in the background section, conventional methods of manufacturing solar cells have been limited to costly and complex processes based primarily on the well-known Siemens process. Formation of useful polycrystalline solar cells formed by direct deposition from liquid and/or gas precursors has not been previously reported. One challenge is the formation of silicon films with desired grain boundary quality. Electrically inactive grain boundaries in the polycrystalline film are of significant importance and will determine the efficiency of charge transport, and therefore the total efficiency of the solar cell or photovoltaic device. Significantly, embodiments of the present invention provide incorporation of hydrogen into the polycrystalline film during deposition of the film. Incorporation of hydrogen into the polycrystalline silicon film acts to passivate the silicon grain boundaries which promotes improved charge transport across the silicon grain boundaries. In some embodiments, hydrogen is injected into the thermal plasma source by mixing with the silicon intermediate compounds such that the hydrogen and silicon are conveyed together. Alternatively, hydrogen is injected into the thermal plasma source separate from the silicon intermediate compounds, such as in a separate channel or plenum.

Hydrogen is provided in a suitable amount to passivate any dangling bonds present in the polycrystalline silicon film. Hydrogen may be conveyed as a separate gas, or alternatively may form part of the plasma stream used in the thermal plasma source. In one example, hydrogen forms part of the plasma stream and the plasma stream is comprised of a mixture of hydrogen and argon (or helium) at a ratio in the range of approximately 0.001 to 1.0 H₂/Ar (or H₂/He). In one example the plasma stream is transported at a flowrate in the range of approximately 1.0 to 1000 l/min.

Embodiments of the present invention provide for post deposition treatment to promote increased grain size and/or preferred orientation of the polycrystalline silicon or silicon-germanium film. Post deposition treatment has proven problematic in the prior art processes, particularly for certain types of substrates. There are two problems associated with thermally processing silicon films on metallic, insulating or composite substrates by regular furnace annealing. One problem is the diffusion of impurities into the films from the substrates. Typical diffusion times vary from minutes to several hours. These time scales match the time spent in furnaces by the silicon film/substrate combination. A second problem is that the use of low melting point substrates, relative to the melting point of silicon (1412 C), are precluded.

Of particular advantage, the inventor has discovered that thermal post deposition treatment may be employed to overcome the limitations of the prior art. In one embodiment of the present invention post deposition heat treatment is carried out (as shown in the figures and described in detail below) by exposing the deposited polycrystalline film to a high intensity, focused linear beam of light that melts the silicon film in linear zones as the beam moves across the film enabling crystal growth and removal of impurities. In another embodiment, the deposited polycrystalline film is exposed to a pulsed, large area beam of light that melts the film as the beam moves across the substrates. The molten film recrystallizes after the pulse. The heat source may be comprised of any suitable mechanism, such as without limitation a pulsed laser source, white light source, rapid thermal processing (RTP), high intensity arc lamps, resistive heater elements, and the like.

Embodiments of the present invention provide methods of post deposition heat treatment of the deposited polycrystalline silicon or silicon-germanium films to increase grain size. For doped films, post deposition heat treatment may be employed to increase dopant activation. Examples of types of post deposition heat treatment that may be used include, without limitation: CW laser annealing, thermal plasma annealing, arc lamp rapid thermal annealing, continuous strip heater systems, or a pancake coil induction heater.

In another aspect methods of the present invention further comprise carrying out post p-n junction formation heat treatment in order to improve device performance. Other downstream processing steps may be employed as desired, for example electrical contacts and antireflection coatings may be formed on the polycrystalline films by thermal plasma deposition or other means.

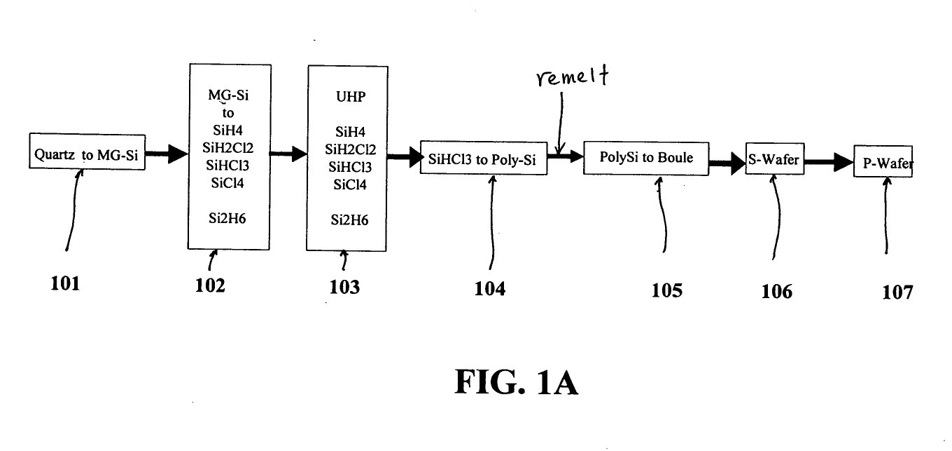

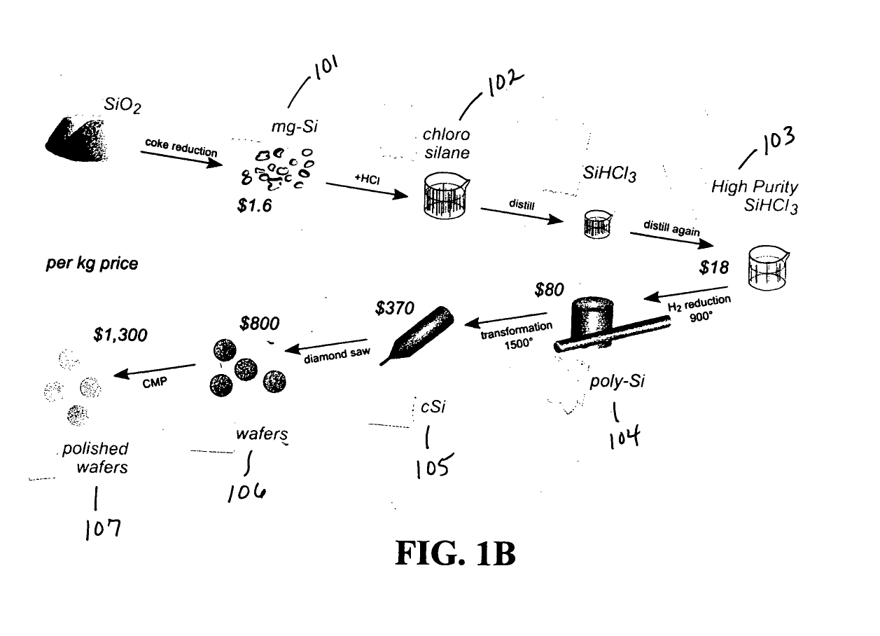

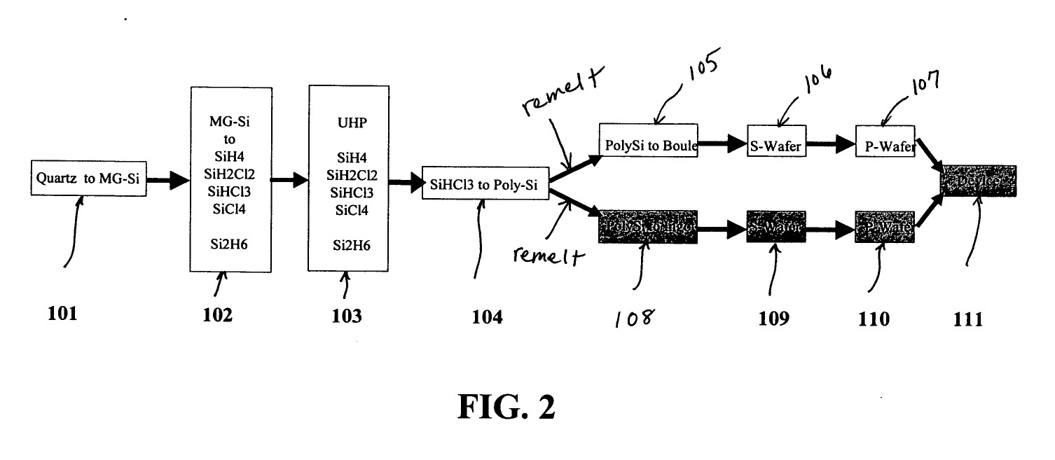

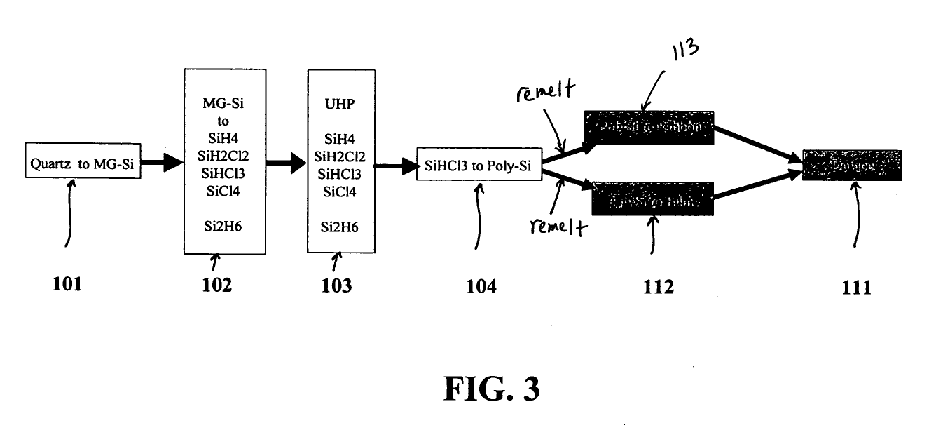

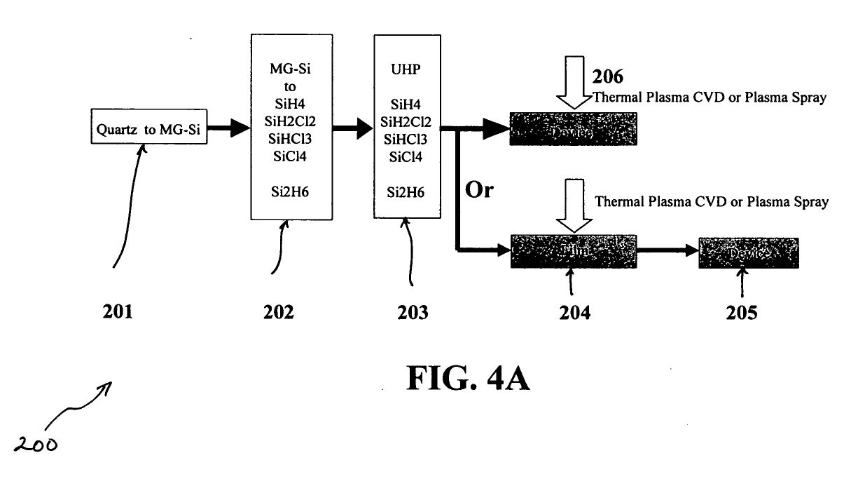

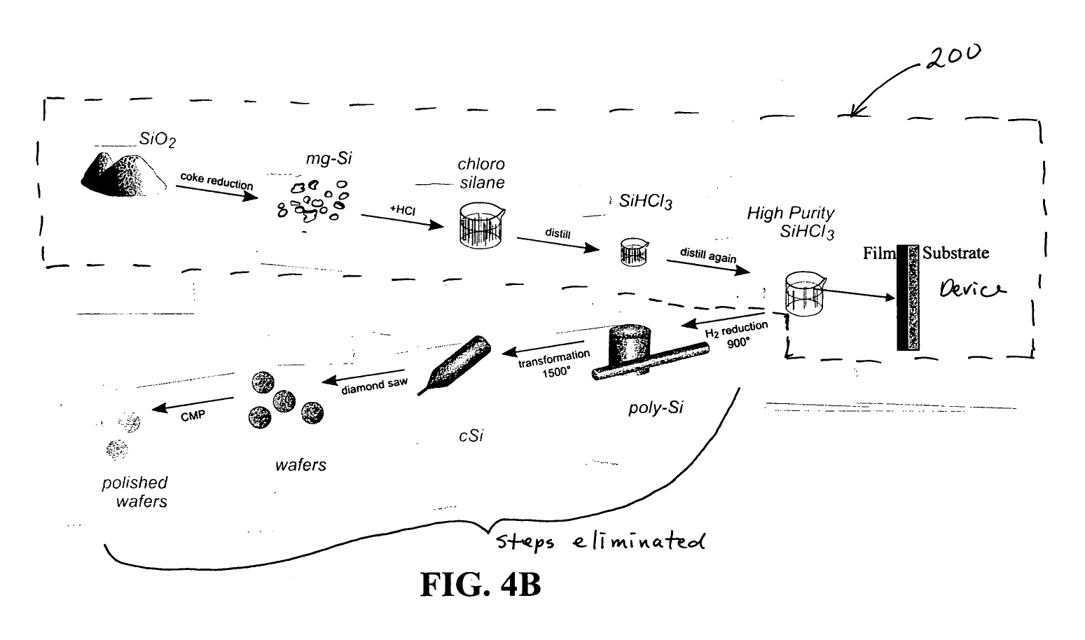

Referring to FIGS. 4A to 7, certain exemplary embodiments of the present invention are shown. Of significant advantage, as illustrated in FIG. 4B methods and systems 200 of the present invention “intercept” the conventional silicon manufacturing process at the end of step 103, where high purity intermediates are already available, and prior to formation of the bulk silicon in step 104 (shown in FIGS. 1A, 2 and 3). Moreover, the present invention does not require re-melting of bulk silicon as required in all of the conventional processes. This results in considerable savings in resources, time and cost.

FIG. 4A illustrates a simplified schematic process diagram showing a system and method for producing silicon solar cells according to some embodiments of the present invention. In general, the exemplary method 200 comprises reduction of quartz with carbon to produce metallurgical grade silicon in step 201, conversion of metallurgical grade silicon to intermediate compounds such as silane, disilane, mono-chlorosilane, di-chlorosilane, tri-chlorosilane and tetra-chlorosilicon by reaction with hydrogen chloride in step 202, and purification of the intermediate compounds in step 203. Next, in one embodiment a polycrystalline film is formed directly on one or more substrates by thermal processing as shown in step 204 and subsequent processing is performed in step 205 to form junctions and the like to provide the solar cell or photovoltaic device. Alternatively, the solar cell or photovoltaic device is formed directly by thermal processing in step 206. Of particular advantage, films and devices are formed by the present invention without the steps necessary in the prior art methods of hydrogen reduction and pyrolysis of the intermediate compounds to form the bulk polycrystalline silicon, remelting of the bulk polysilicon, growth of single or multicrystalline boules or ingots, sawing and polishing of wafers, as illustrated by the reference to “steps eliminated” in FIG. 4B.

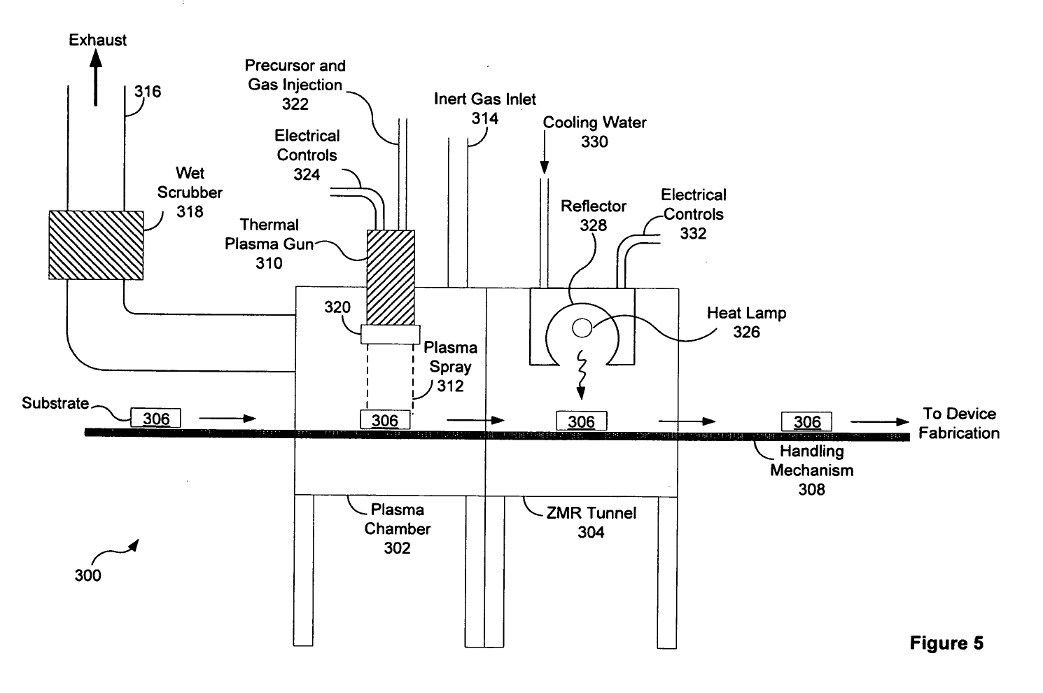

One exemplary embodiment of a system 300 of the present invention is shown in more detail in FIG. 5, a simplified cross sectional view. In this example, a roll-to-roll or a cluster-tool type automated, continuous system is provided. Other systems may also be adapted within the teaching of the present invention. In general, system 300 comprises a plasma chamber 302 and zone melt recrystallization (ZMR) chamber (or tunnel) 304 though which substrates 306 are conveyed on handling mechanism 308. Plasma chamber 302 includes a thermal plasma gun 310 for generating a thermal plasma spray 312 to deposit the polycrystalline silicon or silicon-germanium film on the surface of substrate 306. In some embodiments inert gas is conveyed to the plasma chamber 302 via inert gas inlet 314. Plasma chamber 302 is evacuated by exhaust plenum 316. Gases from the plasma chamber preferably pass through wet scrubber 318 prior to being exhausted.

Thermal plasma gun 310 typically includes an outlet 320 through which the plasma spray 312 is emitted, at least one inlet 322 configured to inject the silicon or silicon germanium intermediate compounds, hydrogen, and other gases or liquids as needed into the thermal plasma gun 310. Electrical controls 324 are coupled to the thermal plasma gun 310 to provide power sufficient to generate the plasma spray.

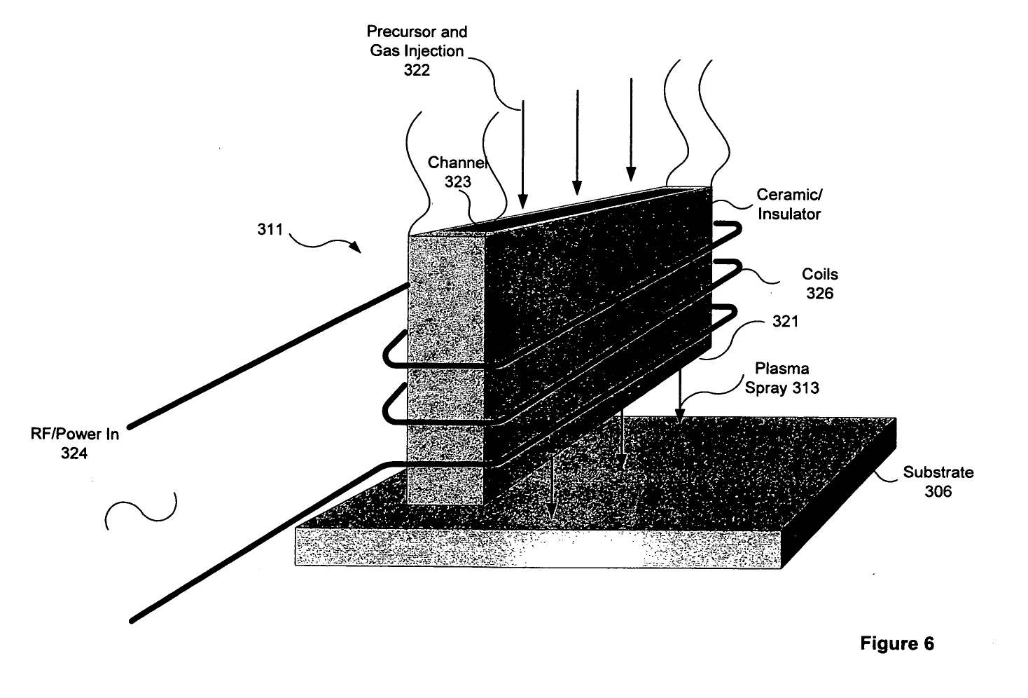

Referring to FIG. 6 another embodiment of a thermal plasma gun 311 is shown in more detail. In this embodiment thermal plasma gun 311 is comprised of a linear, elongated shape and is made of a ceramic/insulator material. Thermal plasma gun 311 is RF inductively coupled through coils 326. In this embodiment, plasma spray 313 is emitted in an elongated, linear pattern as opposed to a showerhead type plasma spray pattern. Precursor liquids, hydrogen, and/or other gases or liquids are injected into the gun 311 through elongated inlet channel 323 and the linear plasma spray 313 is emitted from an elongated outlet channel 321. Preferably, the elongated linear plasma spray 313 pattern extends the substantial length of the substrate, so that the polycrystalline film is deposited across the substantial length of the substrate as the substrate is conveyed past the elongated outlet channel 321.

As described above, the one or more substrates 306 may pass through the visible portion of the plasma spray plume. Alternatively, the one or more substrates may be located below or downstream of the visual plasma spray plume. In one embodiment the substrates are conveyed past the plasma spray plume at a distance of anywhere up to about 10 cm below the plume. In some embodiments handling mechanism 308 includes one or more substrate heaters (not shown) to heat the substrates 306 during processing. Alternatively handling mechanism 308 may be comprised of a conveyor belt and substrates 308 are carried in heated substrate holders (not shown) placed on the belt.

In some embodiments, the present invention provides post deposition thermal processing which may be used to increase the grain size of the deposited polycrystalline film, restructure the silicon grains, promote further passivation of the silicon grains, and/or remove impurities. In another embodiment, post deposition thermal processing may be used to activate dopants present in the as deposited polycrystalline film. Referring again to FIG. 5 a ZMR chamber 304 is coupled to the plasma chamber 302. In the exemplary embodiment, ZMR chamber typically includes heating mechanism 326 for heating the substrate and deposited polycrystalline film, as the substrate is conveyed through the chamber 304. Any suitable type of heating mechanism 326 may be used. In one embodiment, heating mechanism 326 includes a heat lamp and reflector 328 configured to focus and emit a high intensity, linear beam of light onto the substrate 306. Alternatively, heating mechanism 326 is configured to emit a large area, high intensity pulsed beam of light directed onto the substrate. In some embodiments, the large area beam of light is defined as light that covers at least the substantial area of the substrate. Cooling water may be provided via cooling water inlet 330. Heating mechanism 326 is generally powered through suitable electrical controls 332. Other types of heating mechanisms that may be employed include, without limitation: CW laser annealing, thermal plasma annealing, arc lamp rapid thermal annealing, continuous strip heater systems, or a pancake coil induction heater.

Those of skill in the art will recognize that the foregoing specific embodiments are illustrative, and that other specific arrangements and equipment are possible within the spirit and scope of the present invention.

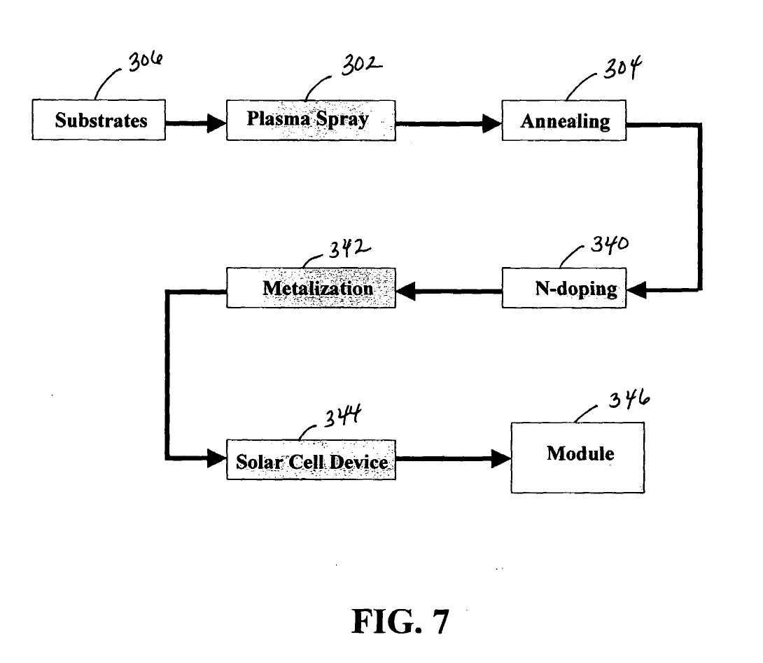

In some applications, additional post deposition processing steps may be provided as shown FIG. 7. Following deposition of the polycrystalline film in chamber 302 and heat treatment in tunnel 304, the substrates may be further processed by incorporating n- or p-dopants in the polycrystalline film in a doping chamber 340, followed by metallization of the substrates in a suitable metallization system 342 to form a solar cell device 344. The solar cell device 344 may then be incorporated into a solar cell module 346 and installed as appropriate.

For solar cell fabrication as shown schematically in FIG. 7, doped films may be deposited on substrates and a p-n junction formed by implantation, diffusion or a spin-on coating of a dopant of opposite polarity or type into the film or alternatively by depositing a thin layer of doped film of opposite polarity or type, hence, directly forming a junction. Post deposition thermal treatment can be used to improve the microstructure, dopant activation and hence electrical quality of the films before and/or after formation of the PN junction. Electrical contacts and antireflection coatings can also be formed on these devices by thermal plasma deposition or other means.

Additionally, the present invention provides for manufacture of junction and/or multi-junction silicon solar cells or photovoltaic devices. Electrical junctions, such and p-n and n-p junctions or a PIN junction may be formed. In some embodiments as described above, dopants may be added directly to the film during the thermal processing step to form a doped polycrystalline silicon or silicon-germanium film. For example, dopants such as BCl₃, AlCl₃ or POCl₃ and the like are added to the silicon intermediates in controlled amounts to give p-type or n-type silicon with desired dopant concentrations. These dopants are provided in liquid and/or gaseous form and may be mixed with the silicon intermediates and injected into the thermal plasma source together, or alternatively may be separately conveyed to the thermal plasma source. The junctions may be deposited sequentially form p-n or n-p layers in the polycrystalline silicon or silicon-germanium films directly. In either instance, the method and system of the present invention is particularly suited to enable incorporation of controlled concentrations of dopants as desired since the dopants are added directly as the film is deposited. Although direct incorporation of dopants during formation of the film is preferred for some applications, alternative embodiments may also be employed. For example, p-n or n-p junctions may be prepared using spin-on dopants and heat treatment. Alternatively, p-n or n-p junctions may be formed by thermal plasma ion implantation, plasma immersion ion implantation, gas phase diffusion, and/or by chemical vapor deposition (CVD) growth of the complimentary dopant type film, and the like.

Embodiments of the thermal plasma deposition process described herein provide a fast deposition process, carried out essentially at atmospheric pressure or at reduced pressure, capable of large scale production of low cost polycrystalline silicon or silicon-germanium photovoltaic cells having a large area form factor in an automated, continuous fashion.

### EXPERIMENTAL

A number of experiments were performed according to embodiments of the methods and systems of the present invention. The experiments described below are provided for illustration purposes only, and are not intended to limit the scope of the present invention in any way.

### Powder Spray

High purity silicon (˜99.995%) powder of −325 mesh size was thermal plasma sprayed using a 100 Kilowatt thermal plasma gun in a low pressure plasma system. The substrates used were mild steel, stainless steel, aluminum nitride, quartz, high purity alumina, borosilicate glass, Corning 1737 glass, Zircar RS-95 alumina fiber composite sheet, tungsten coated alumina, molybdenum coated alumina and Al:SiC composite sheet.

A total of six thermal plasma spray depositions were done while varying parameters like powder feed rate, argon/hydrogen ratio and substrate to plasma gun distance.

The thickness of the silicon film on the 2 inch×2 inch substrates was measured to be between 4 and 5 mils. Cross-sectional optical microscopy and scanning electron microscopy indicated conformal coatings with relatively large grain size and very low porosity. Powder x-ray diffraction spectra indicated that the as deposited films are polycrystalline in nature and having a typical silicon powder pattern.

### Liquid Precursor Spray

Silicon tetrachloride (SiCl₄) of greater than 99.5% purity was used as the liquid precursor. A 35 Kilowatt thermal plasma gun was used in both an external feed mode and an internal feed mode configuration.

A total of six thermal plasma spray depositions were done while varying parameters like argon/hydrogen ratio, electrical power to the thermal plasma gun and substrate to gun distance.

The substrates used were graphite, alumina, Corning glass and quartz. X-ray diffraction indicated the as deposited films were polycrystalline in nature having a typical silicon powder pattern.

The thickness of the silicon films deposited was measured to be about 2 mils and optical microscopy showed a conformal coating with a mix of plate like and granular surface morphology. Films deposited by the internal feed mode showed better quality and liquid precursor utilization.

### CO₂ Laser Annealing

A 300 Watt RF excited CO₂ laser was used for annealing the as deposited films. The parameters varied were the pulse period and the pulse width. This dictates the average power seen by the substrate. Another parameter varied was the substrate scan velocity with respect to the beam.

Depending on the parameters, under-melting to controlled melting to catastrophic melting of the film/substrate system was obtained. These results indicate that pulsed laser annealing has the potential to function as a zone melt and recrystallization tool.

X-ray diffraction studies indicated an increase in the grain size by a factor of 4, preferential (220) orientation and reduction in strain in the film.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. All patents, patent applications, publications, and references cited herein are expressly incorporated by reference to the same extent as if each individual publication or patent application was specifically and individually indicated to be incorporated by reference.

I claim:

1. A method of forming a solar cell or photovoltaic device, characterized in that: one or more silicon intermediates in liquid and/or gaseous form are thermally processed with hydrogen to form a polycrystalline silicon film directly on a substrate, wherein said thermal processing is configured to promote enhanced grain quality of the polycrystalline silicon film as formed.

2. The method of claim 1 wherein said thermal processing is carried out by thermal plasma spray deposition.

3. The method of claim 1 wherein said thermal processing is carried out by thermal plasma enhanced chemical vapor deposition.

4. The method of claim 1 wherein said thermal processing further comprises:
forming a high temperature gas or plasma comprised of any one or more of helium, hydrogen, argon, or mixtures thereof.

5. The method of claim 1 wherein said silicon intermediates further comprise a mixture of liquid and/or gaseous compounds with solid silicon compounds.

6. The method of claim 1 wherein said silicon intermediates are selected from any one or more of SiH₄, Si₂H₆, SiH₂Cl₂, SiHCl₃, SiCl₄, or combinations thereof.

7. The method of claim 1 wherein said thermal processing further comprises: mixing one or more germanium intermediates with said silicon intermediates to form a polycrystalline silicon-germanium film.

8. The method of claim 1 wherein said thermal processing further comprises: mixing one or more dopant compounds, concurrently with said silicon intermediates, or subsequently, to form a doped polycrystalline silicon film.

9. The method of claim 8 wherein said dopant compounds are selected from any one or more of: BCl₃, AlCl₃, POCl₃ or combinations thereof.

10. The method of claim 1 wherein said substrate is comprised of any one or more of: metal, semiconductor, insulator, ceramic, glass, any dielectric material, or combination thereof.

11. The method of claim 7 wherein said germanium intermediates are selected from any one of more of: GeCl₄, GeH₄, or combinations thereof.

12. A method of forming a solar cell or photovoltaic device, comprising:
generating a plasma stream in a thermal plasma source;
injecting one or more silicon intermediate compounds in liquid and/or gaseous form into thermal plasma source wherein the silicon intermediate compounds dissociate;
injecting hydrogen into the thermal plasma source; and
depositing a polycrystalline silicon film on the surface of one or more substrates located proximate said thermal plasma source, wherein hydrogen is incorporated into the polycrystalline silicon film to promote passivation of silicon grains formed in the polycrystalline silicon film.

13. The method of claim 12 wherein the thermal plasma source is operated at a temperature in the range of approximately 2000 K to 20,000 K.

14. The method of claim 12 further comprising:
first injecting silicon particles onto said substrates to form a silicon seed layer thereon, prior to injecting the one or more silicon intermediate compounds.

15. The method of claim 12 further comprising:
heat treating the polycrystalline silicon film formed on the one of more substrates.

16. The method of claim 12 further comprising:
injecting one or more germanium intermediate compounds with said silicon intermediate compounds to form a polycrystalline silicon-germanium film.

17. The method of claim 16 wherein said germanium intermediate compounds are selectively injected such that the composition of silicon to germanium (Si/Ge) is controllable.

18. The method of claim 12 wherein said plasma stream is comprised of any one or more of helium, hydrogen, argon, or mixtures thereof.

19. The method of claim 12 further comprising mixing one or more dopant compounds, concurrently with said silicon intermediate compounds, or subsequently, to form a doped polycrystalline silicon film on the surface of one or more substrates.

20. The method of claim 12 wherein said silicon intermediate compounds are selected from any one or more of SiH₄, Si₂H₆, SiH₂Cl₂, SiHCl₃, SiCl₄, SiBr₄, SiHBr₃, SiH₂Br₂, SiI₄, SiH₁₃, SiI₂, or combinations thereof.

21. The method of claim 19 wherein said dopant compounds are selected from any one or more of: BCl₃, AlCl₃, POCl₃ or combinations thereof.

22. The method of claim 19, further comprising:
sequentially depositing p and n doped polycrystalline silicon layers, or n and p doped polycrystalline silicon layers, to form respective p/n or n/p junctions directly on said one or more substrates.

23. The method of claim 12 wherein hydrogen is incorporated into the polycrystalline silicon film at a concentration in the range of approximately 0.0001 to 1 atomic %.

24. The method of claim 12 wherein the plasma stream is flowed at a flowrate in the range of approximately 1.0 to 1000 l/min.

25. The method of claim 12 wherein the silicon intermediate compounds are injected at a flowrate in the range of approximately 0.1 to 1000 ml/s.

26. The method of claim 12 wherein deposition is carried out at a pressure in the range of approximately 1 to 760 Torr, or at positive pressure.

27. The method of claim 12 wherein said plasma stream is comprised of a mixture of hydrogen and argon at a ratio in the range of approximately 0.001 to 1.0 H₂/Ar.

28. The method of claim 12 wherein said one or more substrates are located proximate the thermal plasma source at a distance such that the one or more substrates are immersed in the visible plume of the plasma, to about 4 cm below the visible plume.

29. The method of claim 12, further comprising:
subsequently forming a p/n or n/p junction on said polycrystalline silicon film by any one or more of: implantation, diffusion, spin-on coating or deposition.

30. The method of claim 12 wherein hydrogen is injected by mixing with the silicon intermediate compounds.

31. The method of claim 12 wherein hydrogen is injected into the thermal plasma source separate from the silicon intermediate compounds.

32. The method of claim 12 wherein the thermal plasma source is operated at a power in the range of approximately 1 to 300 KWatts.

33. A method of forming a solar cell or photovoltaic device, comprising the steps of:
converting metallurgical grade silicon to one or more silicon intermediate compounds by reaction with hydrogen halides;
purifying said silicon intermediate compounds to form silicon intermediate compounds of approximately 99.5% purity and greater;
generating a plasma stream in a thermal plasma source, said plasma stream including hydrogen;
injecting said purified silicon intermediate compounds in liquid and/or gaseous form into the thermal plasma source wherein the silicon intermediate compounds dissociate;
injecting hydrogen into the thermal plasma source; and
depositing a polycrystalline silicon film on the surface of one or more substrates located proximate said thermal plasma source, said polycrystalline silicon film exhibiting enhanced grain quality.

34. A solar cell or photovoltaic device, comprising:
a substrate; and
a polycrystalline silicon film formed on said substrate according to the method of claim 12.

35. A system for manufacturing a solar cell or photovoltaic device, comprising:
a handling mechanism configured to support and transport one or more substrates;
a plasma chamber comprising a thermal plasma spray gun configured to generate a thermal plasma spray to deposit a polycrystalline silicon or silicon-germanium film on the surface of the one or more substrates as the substrates are conveyed through the plasma chamber; and
a post deposition chamber comprising at least one heating mechanism configured to generate a beam of light that melts the polycrystalline silicon or silicon-germanium film in linear zones as the one or more substrates are conveyed through the post deposition chamber.

36. The system of claim 35, wherein said thermal plasma spray gun further comprises: an elongated, linear outlet configured to generate an elongated, linear thermal plasma spray.

37. The system of claim 35 where the heating mechanism is configured to generate a pulsed, large area beam of light.

38. The system of claim 35 where the heating mechanism is configured to generate a focused, linear beam of light.
